(19) United States
(12) Patent Application Publication
(10) Pub. No.: US 2014/0372669 A1
(43) Pub. Date: Dec. 18, 2014

(54) MEMORY CONTROL SYSTEM AND MEMORY INTERFACE METHOD USING THE SAME

(71) Applicant: Electronics and Telecommunications Research Institute, Daejeon (KR)

(72) Inventors: Hyuk Je KWON, Seoul (KR); Youngseok Choi, Daejeon (KR)

(73) Assignee: Electronics and Telecommunications Research Institute, Daejeon (KR)

(21) Appl. No.: 14/039,884

(22) Filed: Sep. 27, 2013

(30) Foreign Application Priority Data
Jun. 17, 2013 (KR) 10-2013-0069253

(51) Int. Cl. G06F 12/02; G06F 9/30; G11C 11/406

(52) U.S. Cl. CPC G06F 12/0246; G11C 11/406; G06F 9/3004
USPC 711/103; 711/105; 711/154

(57) ABSTRACT

A memory control system includes: a memory that stores data; a memory controller that controls operation of the memory by a memory control signal; and a CPU that forms a single link with the memory controller and transmits the memory control signal to the memory controller via the single link.

### CROSS-REFERENCE TO RELATED APPLICATION

This application claims priority to and the benefit of Korean Patent Application No. 10-2013-0069253 filed in the Korean Intellectual Property Office on Jun. 17, 2013, the entire contents of which are incorporated herein by reference.

### BACKGROUND OF THE INVENTION

(a) Field of the Invention

The present invention relates to a memory control system and a memory interface method using the same.

(b) Description of the Related Art

In general, an external memory can be accessed through a memory controller present within or outside a central processing unit (CPU).

Accordingly, conventional methods for controlling an external memory include interfacing by a central processing unit (CPU) and an external memory controller, and interfacing by a memory controller embedded in a CPU. These two methods are the same in terms of basic operation.

Also, a conventional CPU or memory controller uses a bus to control a memory. A bus for memory control typically consists of about 200 lines. The number of lines in the memory bus increases as (number of corresponding channels×bus width) increases, depending on how many channels the CPU supports. An increased number of lines should be placed and arranged while avoiding collision with other devices.

FIG. 1 is a view showing a control scheme using a memory bus formed within or outside a CPU according to the conventional art.

That is, communications between various other devices and a CPU are carried out through a bus, and a memory is a device for loading data on the bus. However, in this situation which requires fast access for high-speed and large-capacity communications, there are some limitations in expanding the memory bus, increasing the capacity of a memory module, and increasing speeds.

### SUMMARY OF THE INVENTION

The present invention has been made in an effort to provide a memory control system which is capable of high-speed communication and data processing, and a memory interface method using the same.

An exemplary embodiment of the present invention provides a memory control system including: a memory that stores data; a memory controller that controls the operation of the memory by a memory control signal; and a CPU that forms a single link with the memory controller and transmits the memory control signal to the memory controller via the single link.

The memory control signal may include a command signal and data, and the single link may allow the command signal and the data to be simultaneously transmitted in one serial packet.

The command signal may include at least one of the following: a command that requires a response; a command that requires no response; a command that requires a response indicating only simple status information; and an internal command by which no external command is required.

The serial packet may include at least one of request and response commands for a transaction layer packet (TLP) or data link layer packet (DLLP).

The memory controller and the CPU each may include: a transaction layer for packetizing commands and operations; a physical layer for analog transmitting a serial packet generated in the transaction layer through a circuit; and a data link layer for transmitting data by using the physical layer.

The single link may include a serial link, and the serial link may be connected through the physical layers of the memory controller and CPU.

Another exemplary embodiment of the present invention provides a memory control system including: a memory that stores data; a CPU that generates a memory control signal and controls operation of the memory; and a serial packet controller that receives the memory control signal and transmits the same to the memory.

The CPU may include a memory controller that generates a memory control signal, a serial link may be formed between the memory controller and the serial packet controller, and the memory control signal may be transmitted to the serial packet controller via the serial link.

The memory may include at least one non-volatile memory, such as flash memory or EEPROM, which performs operations using basic commands Read and Write.

The memory may include a volatile memory which performs Read and Write operations, and also performs operations using Refresh, Precharge, and Active commands, to keep internal data.

The serial packet controller may include: a transaction layer for packetizing commands and operations; a physical layer for analog transmitting a serial packet generated in the transaction layer through a circuit; and a data link layer for transmitting data by using the physical layer.

The serial packet may include at least either one of a command signal and data.

The serial packet controller may execute decoding of commands from the memory controller, and may packetize the execution result.

Yet another exemplary embodiment of the present invention provides a memory interface method by which a memory controller controls the operation of a memory, the method including: the memory controller generating a serial packet including at least either one of a command signal and data; the memory controller transmitting the serial packet to the memory and sending a request for status information or data to the memory; and the memory sending the status information or data as a response to the memory controller.

The memory interface method may further include sending a notification that an available segment for new command execution is required.

In the sending of a request for status information or data, the status information or data may be transmitted via a single link.

The serial link may include a serial link, and the serial link may be formed between the memory controller and the memory.

The serial packet may include request and respond commands for a transaction layer packet (TLP).

### BRIEF DESCRIPTION OF THE DRAWINGS

FIG. 1 is a view showing a control scheme using a memory bus formed within or outside a CPU according to the conventional art.

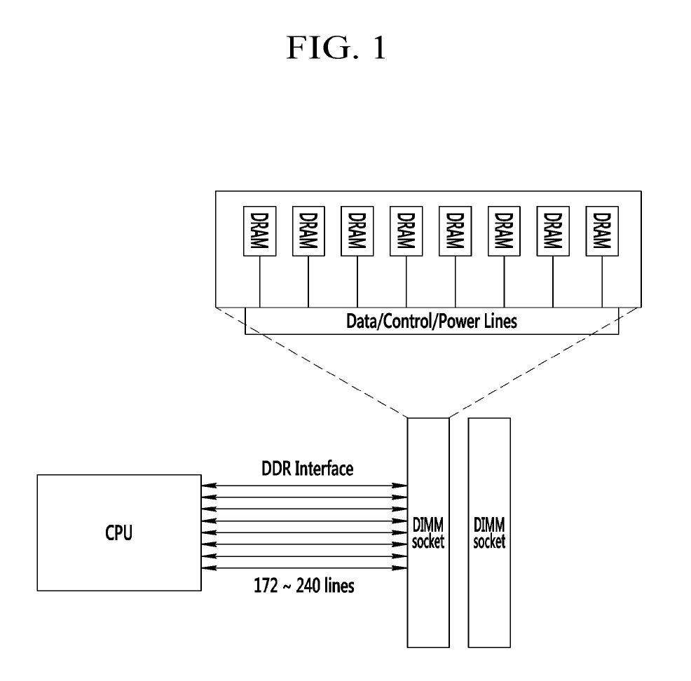

FIG. 2 is a block diagram of a memory control system in accordance with an exemplary embodiment of the present invention.

FIG. 3 is a block diagram of a memory control system having a memory controller formed within a CPU in accordance with another exemplary embodiment of the present invention.

FIG. 4 is a view showing a serial link formed in accordance with an exemplary embodiment of the present invention.

FIG. 5 shows a packet structure for a TLP request with data in accordance with an exemplary embodiment of the present invention.

FIG. 6 shows a packet structure for a TLP request with no data in accordance with an exemplary embodiment of the present invention.

FIG. 7 shows a packet structure for a TLP response with data in accordance with an exemplary embodiment of the present invention.

FIG. 8 shows a packet structure for a TLP response with status information in accordance with an exemplary embodiment of the present invention.

FIG. 9 shows a packet structure for a vendor-specific data link layer in accordance with an exemplary embodiment of the present invention.

FIG. 10 is a flowchart for explaining a memory interface method in accordance with an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

Throughout the specification and claims, unless explicitly described to the contrary, the word “comprise” and variations such as “comprises” or “comprising” will be understood to imply the inclusion of stated elements but not the exclusion of any other elements.

In addition, the terms “-er”, “-or”, and “module” described in the specification mean units for processing at least one function or operation, and can be implemented by hardware components or software components and combinations thereof.

Hereinafter, a memory control system and a memory interface method using the same in accordance with an exemplary embodiment of the present invention will be described in detail with reference to the accompanying drawings.

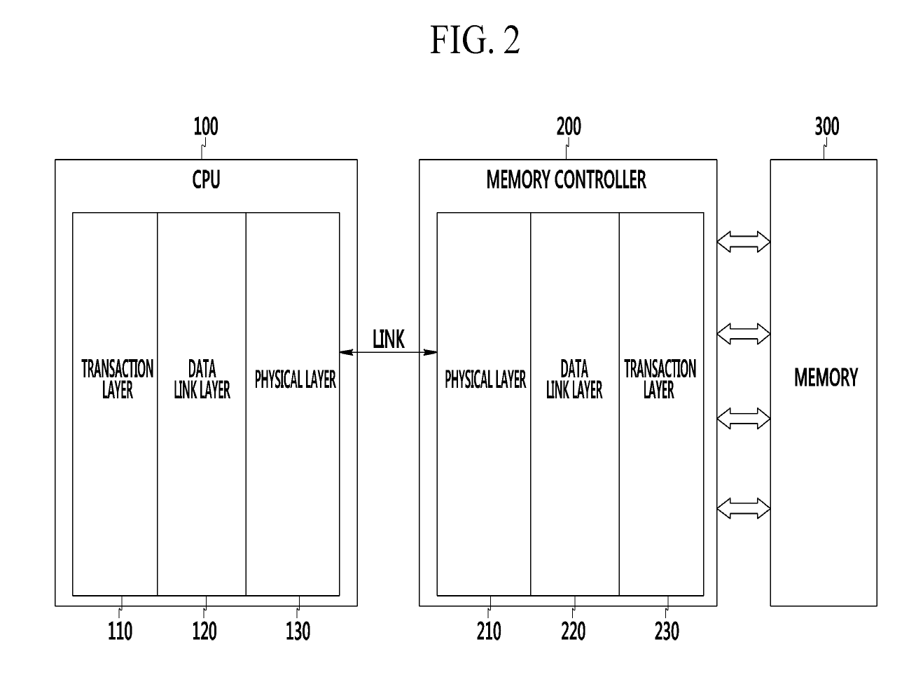

FIG. 2 is a block diagram of a memory control system in accordance with an exemplary embodiment of the present invention.

Referring to FIG. 2, a memory control system in accordance with an exemplary embodiment of the present invention includes a CPU 100, a memory controller 200, and a memory 300. It should be noted that only the components required for explanation of the exemplary embodiment of the present invention are illustrated, but the present invention is not limited to these components.

A central processing unit (CPU) 100 generates a memory control signal, and then transmits the memory control signal to the memory controller 200.

The memory controller 200 is formed outside the CPU 100. The memory controller 200 controls the operation of the memory 200 by using the memory control signal transmitted from the CPU 100.

A single link including a serial link is formed between the CPU 100 and the memory controller 200 in accordance with one exemplary embodiment of the present invention. The CPU 100 transmits a memory control signal to the memory controller 200 via the single link.

Here, the memory control signal includes either one or both of a command signal for controlling the memory 300 and data stored in the memory 300. Accordingly, if a memory control signal in accordance with an exemplary embodiment of the present invention includes both a command signal and data, the single link can transmit the command signal and the data simultaneously in one serial packet.

The memory 300 stores data, and performs an operation according to an external control signal such as a memory control signal. The memory 300 in accordance with the exemplary embodiment of the present invention includes a DDR SDRAM (double data rate synchronous DRAM).

Also, the memory 300 may be a non-volatile memory or a volatile memory.

Flash memory, EEPROM, etc., which are non-volatile memories, support basic commands Read and Write, and perform operations using several other commands.

SDRAM, which is volatile memory, performs operations using commands Refresh, Precharge, and Active, as well as Read and Write operations, and supports basic operating commands for keeping internal data in a power-up state.

Referring to FIG. 2, the memory controller 200 is formed outside the CPU 100, and a serial link is formed between the CPU 100 and the memory controller 200.

In this case, a memory control signal from the CPU 100 is transmitted to the external memory controller 200 via the serial link to make an attempt to access memory.

The CPU 100 and the memory controller 200 each include a transaction layer (110, 230), a data link layer (120, 220), and a physical layer (130, 210).

The transaction layer completes the transmission and reception of packets at a system level. The transaction layer 110 packetizes a requirement (e.g., command or operation) generated by the system and transmits it to a lower layer. Then, the transaction layer of a remote device receives the packet, thereby completing communication between a local device and the remote device by terminating the packet. The remote device may be the CPU 100, and generates transactions. The local device may be the memory 300, and is formed pursuant to a transaction from the CPU 100.

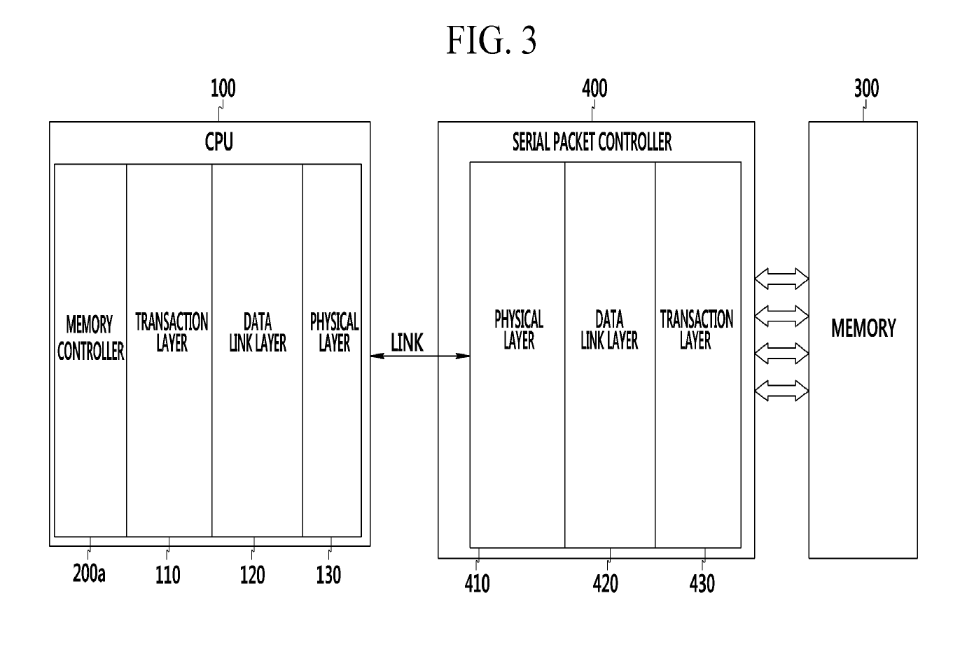

FIG. 3 is a block diagram of a memory control system having a memory controller formed within a CPU in accordance with another exemplary embodiment of the present invention.

Referring to FIG. 3, a memory control system in accordance with another exemplary embodiment of the present invention includes a CPU 100, a serial packet controller 400, and a memory 300. Also, a memory controller 200a is included in the CPU 100.

A serial link is formed between the memory controller 200a embedded in the CPU 100 and the serial packet controller 400. In this case, the CPU 100 controls the memory 300 by the embedded memory controller 200a. Also, the serial packet controller 400 receives a memory control signal and transmits it to the memory. In addition, the serial packet controller 400 functions to execute decoding of the command corresponding to the memory control signal and packetize the execution result.

The CPU 100 and the serial packet controller 400 each include a transaction layer (110, 430), a data link layer (120, 420), and a physical layer (130, 410). The functions of the respective layers have been described above, so their descriptions are omitted.

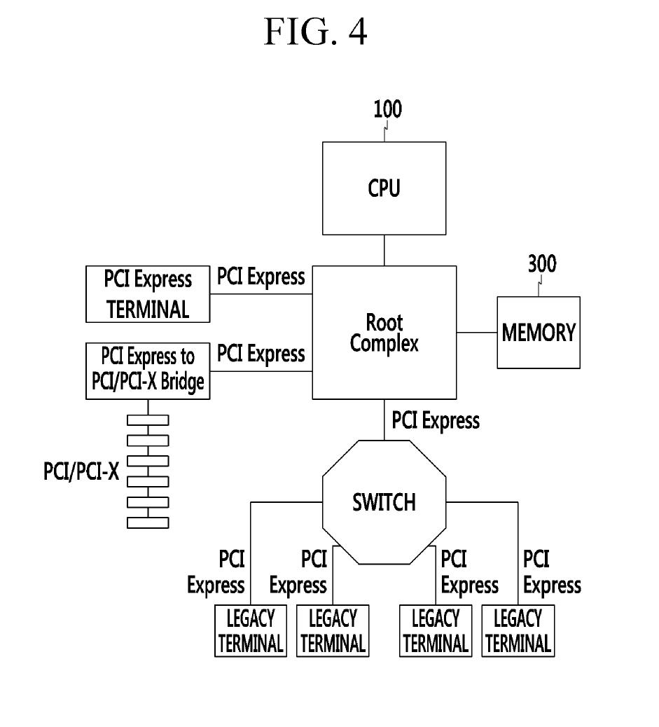

FIG. 4 is a view showing a serial link formed in accordance with an exemplary embodiment of the present invention.

In an exemplary embodiment of the present invention, a serial link is formed in order to reduce communication bottlenecks between the CPU 100 and peripheral equipment. Such a serial link scheme has the advantage of high-speed communication without using a bus, thereby preventing system performance degradation caused by peripheral equipment.

Hereinafter, a command signal and a serial packet in accordance with an exemplary embodiment of the present invention will be described.

In accordance with an exemplary embodiment of the present invention, commands for DDR SDRAM can be configured using the foregoing layer structure. Table 1 shows the commands for DDR SDRAM.

TABLE 1

| Command Type | Abbr. | code(bin) | Format | Layer |
|---|---|---|---|---|
| Mode Register Set | MRS | 0000 xxxx | posted | TLP |
| Refresh | REF | 0001 0000 | posted | TLP |
| Self Refresh Entry | SRE | 0001 0001 | posted | DLLP |
| Self Refresh Exit | SRX | 0001 0010 | non-posted | TLP |
| Single Bank Precharge | PRE | 0010 0000 | posted | DLLP |
| Precharge all Banks | PREA | 0010 0001 | posted | DLLP |
| Bank Active | ACT | 1000 xxxx | posted | DLLP |
| Write (Fixed BL8 or BC4) | WR | 0011 0000 | posted | TLP |
| Write (BC4, on the Fly) | WRS4 | 0011 0001 | posted | TLP |
| Write (BL8, on the Fly) | WRS8 | 0011 0010 | posted | TLP |
| Write with Auto Precharge | WRA | 0011 0011 | posted | TLP |
| (Fixed BL8 or BC4) | | | | |
| Write with Auto Precharge | WRAS4 | 0011 0100 | posted | TLP |
| (BC4, on the Fly) | | | | |
| Write with Auto Precharge | WRAS8 | 0011 0101 | posted | TLP |
| (BL8, on the Fly) | | | | |
| Read (Fixed BL8 or BC4) | RD | 0100 0000 | non-posted | TLP |
| Read (BC4, on the Fly) | RDS4 | 0100 0001 | non-posted | TLP |
| Read (BL8, on the Fly) | RDS8 | 0100 0010 | non-posted | TLP |
| Read with Auto Precharge | RDA | 0100 0011 | non-posted | TLP |
| (Fixed BL8 or BC4) | | | | |
| Read with Auto Precharge | RDAS4 | 0100 0100 | non-posted | TLP |
| (BC4, on the Fly) | | | | |
| Read with Auto Precharge | RDAS8 | 0100 0101 | non-posted | TLP |
| (BL8, on the Fly) | | | | |
| No Operation | NOP | 1111 xxxx | posted | DLLP |
| Device Deselected | DES | 0101 xxxx | posted | DLLP |
| Power Down Entry | PDE | 0110 0000 | posted | DLLP |
| Power Down Exit | PDX | 0110 0001 | non-posted | TLP |
| ZQ Calibration Long | ZQCL | 0111 0000 | non-posted | TLP |
| ZQ Calibration Short | ZQCS | 0111 0001 | non-posted | TLP |

A memory control signal transmitted to the memory 300 through the memory controller 200 or the serial packet controller 400 includes a command signal. The command signal may include at least one of the following: a command (Non-posted) that requires a response, a command (posted) that requires no response, a command (Non-posted) that requires a response indicating only simple status information, and an internal command (Null) by which no external command is required.

A typical command that requires a response is Read. For this command that requires a response, memory data is read by a command from a host wanting to read the data in the memory 300, and is then transmitted to the host.

A typical command that requires no response is Write. For this command that requires no response, data to be written on the memory 300 is received and written on the memory 300 by a command from the host. In this case, no response is required.

The command that requires a response only indicating simple status information does not require multiple pieces of data, like Read, though it may require a response in some cases, and only indicates status information for receiving the next command.

For the internal command by which no external command is required, an operation is performed by a command that is internally generated according to internal logic and rules, rather than by an external command.

The factor values versus command signals in accordance with an exemplary embodiment of the present invention can be classified as shown in the following Table 2.

TABLE 2

| | | In/out |
|---|---|---|
| Abbreviation | Argument | Data |
| MRS | BA, OpCode | x |
| PRE | BA | x |
| ACT | BA, RA | x |
| WR, WRS4, WRS8, WRA, WRAS4, WRAS8, | BA, CA | o |
| RD, RDS4, RDS8, RDA, RDAS4, RDAS8 | | |
| REF, SRE, SRX, PREA, NOP, DES, PDE, | — | x |
| PDX, ZQCL, ZQCS | | |

Here, BA denotes Bank Address, RA denotes Row Address, CA denotes Column Address, and OpCode denotes MRS setting value.

Each of these commands may have one or two factors, or none. In Table 2, data input and out through the Pin DQ of DDR SDRAM is indicated as “In/out data”, and the content entered in BA0-BA2 and A15-A0 is indicated as Argument.

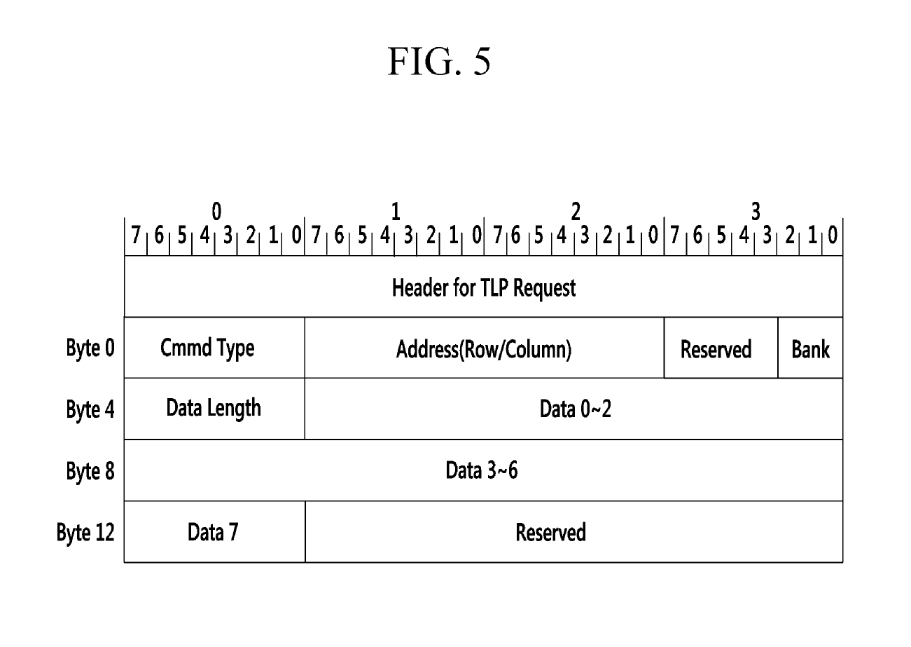

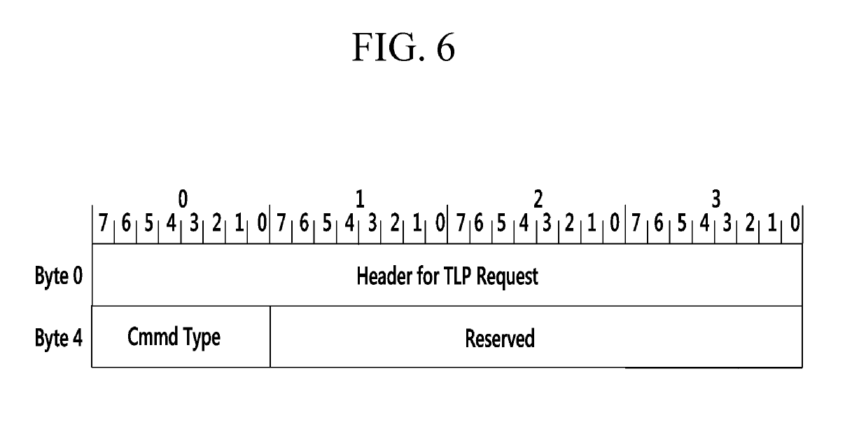

FIG. 5 shows a packet structure for a TLP request with data in accordance with an exemplary embodiment of the present invention, and FIG. 6 shows a packet structure for a TLP request with no data in accordance with an exemplary embodiment of the present invention.

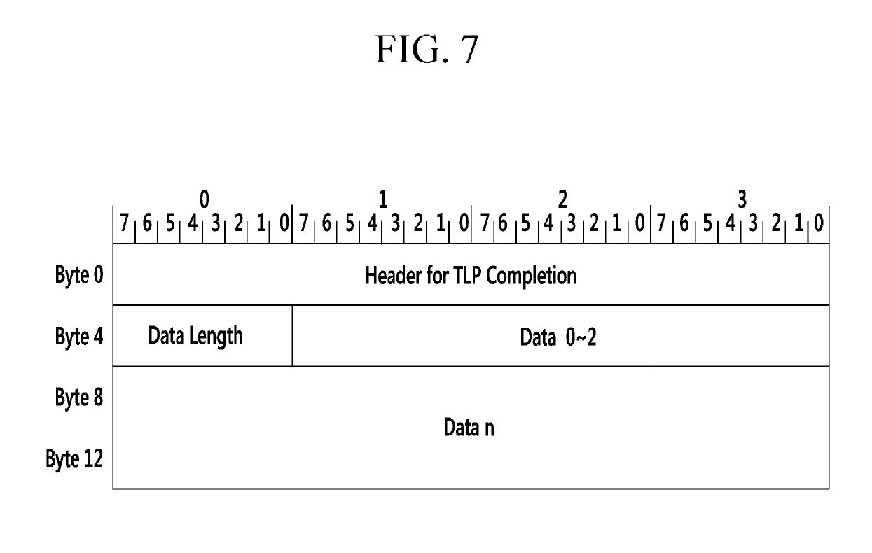

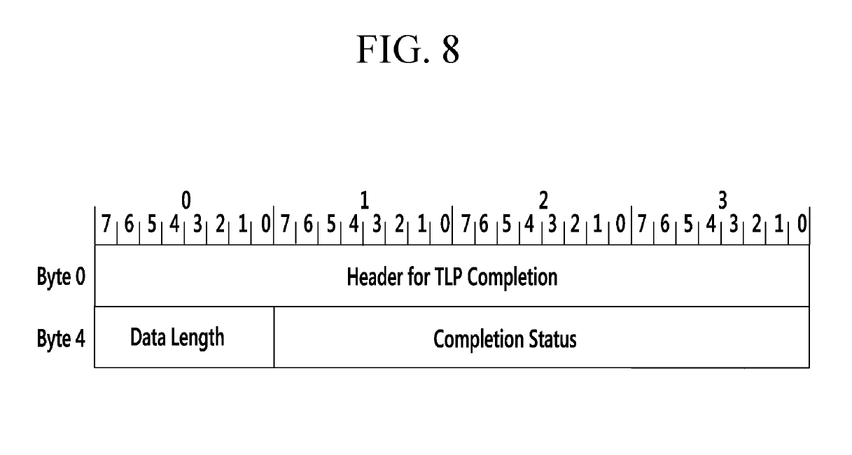

A transaction layer packet (hereinafter, TLP) request is a command given by the top layer, which is of a packet structure for requesting data from a remote location. Commands for transmitting and requesting data to and from the top layer include Read and Write. In addition, there are commands that request or require only status information of DDR SDRAM. Moreover, TLP requests can be classified as shown in FIGS. 7 and 8 according to whether they contain data or not.

FIG. 7 shows a packet structure for a TLP response with data in accordance with an exemplary embodiment of the present invention.

A TLP response (TLP Complete) is in the form of an answer to a TLP request. A requirement from a local location or remote location is carried and transmitted in a TLP response, thereby performing a function of the transaction layer. The TLP response also focuses on Read and Write like the TLP request. In the case of Read, the TLP response carries and transmits data read from DDR SDRAM, as shown in FIG. 8.

FIG. 8 shows a packet structure for a TLP response with status information in accordance with an exemplary embodiment of the present invention.

FIG. 8 depicts a TLP request for a DDR SDRAM status for new command execution.

A DDR SDRAM command requires an available segment for new command execution after the current command is executed and completed. A notification about this requirement is sent to properly process the acceptance of various commands generated from the host.

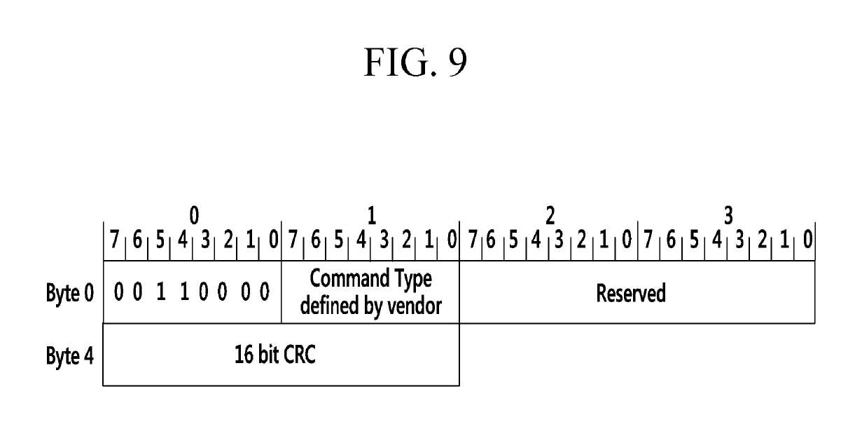

FIG. 9 is a packet structure for a vendor-specific data link layer in accordance with an exemplary embodiment of the present invention.

A data link layer packet (hereinafter, DLLP) is a packet in a data link layer that serves to ensure the integrity of sent and received data. All commands from DDR SDRAM can be processed in the data link layer even if they are not transmitted to a transaction layer. These command types include NOP, DES, PDE, SRE, PREA, ACT, and PRE in Table 1.

Also, these statuses do not need to be reported to a remote location.

There are some DLLPs that ensure data integrity and security of connected links. Further, a DLLP may be made available by users, as shown in FIG. 11.

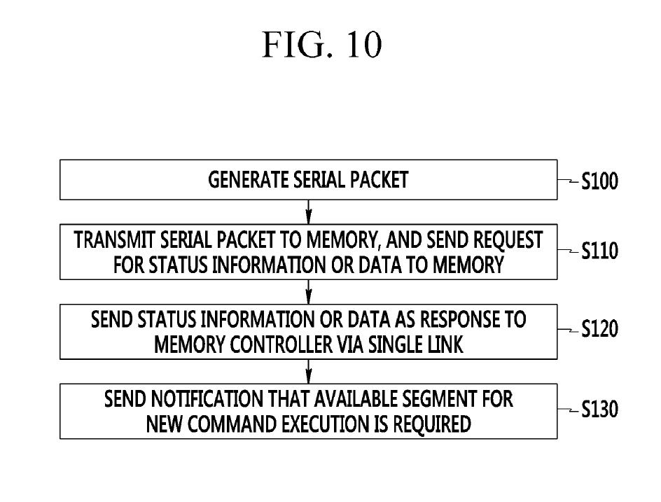

FIG. 10 is a flowchart for explaining a memory interface method in accordance with an exemplary embodiment of the present invention. The flowchart will be described with like reference numerals, in conjunction with the components shown in FIGS. 2 to 4.

Referring to FIG. 10, the memory controller 200 generates a serial packet including at least either one of a command signal and data (S100).

Also, the memory controller 200 transmits the generated serial packet to the memory 300, and requests the memory 300 to send status information or data (S110). In this case, the memory controller 200 may make a request for status information or data by transmitting the serial packet of FIG. 5 and FIG. 6.

The memory 300 sends status information or data in response to the request from the controller 200 (S120). In this case, the memory 300 may transmit status information or data by transmitting the serial packet of FIG. 7 and FIG. 8.

Next, in accordance with one exemplary embodiment of the present invention, the memory 300 executes the current command and completes it, and if an available segment for new command execution is required, the memory 300 sends a notification about this requirement (S130).

As such, an interface method for implementing a memory controller based on high-speed serial communication can improve memory access speed and data transmission rate, with the use of a link, unlike the conventional memory access scheme using a bus. Moreover, the use of a serial link leads to a reduction in the number of physical interface signal lines, thereby enhancing memory expandability.

Using high-speed serial communication has the advantage of improving the data bandwidth of conventional memory by several times, and may improve the overall performance of the system by improving the memory access speed of the CPU.

According to an embodiment of the present invention, communication bottlenecks between a CPU and peripheral equipment are reduced by forming a serial link, and system performance degradation caused by peripheral equipment is prevented by improving the data transmission rate and efficiency of the components through high-speed communication.

The embodiments of the present invention may not necessarily be implemented only through the foregoing devices and/or methods, but may also be implemented through a program for realizing functions corresponding to the configurations of the embodiments of the present invention, a recording medium including the program, or the like.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A memory control system comprising:
a memory that stores data;
a memory controller that controls the operation of the memory by a memory control signal; and
a CPU that forms a single link with the memory controller and transmits the memory control signal to the memory controller via the single link.

2. The memory control system of claim 1, wherein
the memory control signal comprises a command signal and data, and
the single link allows the command signal and the data to be simultaneously transmitted in one serial packet.

3. The memory control system of claim 2, wherein the command signal comprises at least one of the following: a command that requires a response; a command that requires no response; a command that requires a response indicating only simple status information; and an internal command by which no external command is required.

4. The memory control system of claim 2, wherein the serial packet comprises at least one of request and response commands for a transaction layer packet (TLP) or data link layer packet (DLLP).

5. The memory control system of claim 1, wherein
the memory controller and the CPU each comprise:
a transaction layer for packetizing commands and operations;
a physical layer for analog transmitting a serial packet generated in the transaction layer through a circuit; and
a data link layer for transmitting data by using the physical layer.

6. The memory control system of claim 5, wherein the single link comprises a serial link, and the serial link is connected through the physical layers of the memory controller and CPU.

7. A memory control system comprising:
a memory that stores data;
a CPU that generates a memory control signal and controls operation of the memory; and
a serial packet controller that receives the memory control signal and transmits the same to the memory.

8. The memory control system of claim 7, wherein
the CPU comprises a memory controller that generates a memory control signal,
a serial link is formed between the memory controller and the serial packet controller, and the memory control signal is transmitted to the serial packet controller via the serial link.

9. The memory control system of claim 7, wherein the memory comprises at least one non-volatile memory, such as flash memory or EEPROM, which performs operations using basic commands Read and Write.

10. The memory control system of claim 7, wherein the memory comprises a volatile memory which performs Read and Write operations, and also performs operations using Refresh, Precharge, and Active commands, to keep internal data.

11. The memory control system of claim 7, wherein
the serial packet controller comprises:
a transaction layer for packetizing commands and operations;
a physical layer for analog transmitting a serial packet generated in the transaction layer through a circuit; and
a data link layer for transmitting data by using the physical layer.

12. The memory control system of claim 11, wherein the serial packet comprises at least either one of a command signal and data.

13. The memory control system of claim 7, wherein the serial packet controller executes decoding of commands from the memory controller, and packetizes the execution result.

14. A memory interface method by which a memory controller controls operation of a memory, the method comprising:
the memory controller generating a serial packet including at least either one of a command signal and data;
the memory controller transmitting the serial packet to the memory and sending a request for status information or data to the memory; and
the memory sending the status information or data as a response to the memory controller.

15. The method of claim 14, further comprising sending a notification that an available segment for new command execution is required.

16. The method of claim 14, wherein, in the sending of a request for status information or data, the status information or data is transmitted via a single link.

17. The method of claim 16, wherein the serial link comprises a serial link, and the serial link is formed between the memory controller and the memory.

18. The method of claim 14, wherein the serial packet comprises request and respond commands for a transaction layer packet (TLP).
